(19) United States
(12) Patent Application Publication
(10) Pub. No.: US 2013/0164537 A1
(43) Pub. Date: Jun. 27, 2013

(54) METHOD FOR MODIFYING SURFACE OF HYDROPHOBIC POLYMER FILM AND SURFACE-MODIFIED HYDROPHOBIC POLYMER FILM

(71) Applicant: GWANGJU INSTITUTE OF SCIENCE AND TEC, Buk-gu (KR)

(72) Inventors: Sung YANG, Buk-gu (KR); Dong Hee LEE, Buk-gu (KR)

(73) Assignee: GWANGJU INSTITUTE OF SCIENCE AND TECHNOLOGY, Buk-gu (KR)

(21) Appl. No.: 13/632,383

(22) Filed: Oct. 1, 2012

(30) Foreign Application Priority Data
Dec. 21, 2011 (KR) 10-2011-0139513

(51) Int. Cl. B05D 5/00; B32B 27/08; B32B 9/04; B32B 27/30; B32B 27/28; B32B 27/36; C23C 16/44; B32B 27/32

(52) U.S. Cl. 428/412; 427/569; 428/447; 428/516; 428/451; 428/421; 428/419; 428/473.5

(57) ABSTRACT

A method for modifying a surface of a hydrophobic polymer film and surface-modified hydrophobic polymer film are disclosed. The method includes placing a hydrophobic polymer film in a reactor for atmospheric pressure plasma polymerization; supplying a first reaction gas into the reactor to form a physical barrier layer on the hydrophobic polymer film via plasma deposition; and supplying a second reaction gas into the reactor to form a hydrophilic coating layer on the physical barrier layer via plasma deposition. The method enables operation and maintenance of apparatuses and equipment at low cost, and providing efficiency in treatment of large films. Further, the surface-modified hydrophobic polymer film includes a double layer including a physical barrier layer and a hydrophilic coating layer on a polymer film to prevent diffusion of hydrophobic polymer molecules, thereby providing improved surface wettability to the film surface and maintaining hydrophilicity of the film for a long time.

### CROSS-REFERENCE TO RELATED APPLICATION

This application claims the benefit under 35 U.S.C. §119 of Korean Patent Application No. 10-2011-0139513, filed on Dec. 21, 2011 in the Korean Intellectual Property Office, the entirety of which is incorporated herein by reference.

### BACKGROUND

1. Technical Field

The present invention relates a method for modifying a surface of a hydrophobic polymer film and a surface-modified hydrophobic polymer film, and more particularly, to a method for modifying a surface of a hydrophobic polymer film, by which a double layer having different properties is formed on a hydrophobic polymer film through atmospheric pressure plasma polymerization to modify the surface of the hydrophobic polymer film into a hydrophilic surface, and a hydrophobic polymer film, which is surface modified to form a double layer having different properties.

2. Description of the Related Art

With various advantages such as low manufacturing costs, high flexibility, excellent optical transparency, mechanical properties, and the like, polymer films are applied to various fields including medicine, insulation materials, electric materials, packaging materials, optics, fluidic devices, and the like. Most polymer films have hydrocarbon as a main component and thus exhibit hydrophobicity. Hydrophobicity of the polymer films causes low wettability and adhesion, making it difficult to achieve improvement of application range thereof, and thus studies into surface modification of various polymer films have been conducted in the art. Surface modification is a process of changing surface polarity of a material to exhibit hydrophilicity or hydrophobicity. Here, the hydrophilic surface of the material has high surface energy, providing advantages of excellent adhesion with other materials upon bonding or coating.

For surface modification of a polymer film into a hydrophilic surface, gas-phase processing or wet chemical treatment is used [J. Zhou, A. V. Ellis, and N. H. Voelcker, Electrophoresis, vol. 31, pp. 2-16, January 2010]. However, gas-phase processing requires expensive vacuum equipment and chemical treatment is performed through a complicated procedure, causing increase in manufacturing time. In addition, hydrophilicity of the polymer film subjected to surface modification is deteriorated over time due to dissociation of polymer rings or adsorption of other elements to the surface of the polymer, causing restoration of hydrophobicity of the polymer film. Furthermore, for the polymer film subjected to surface modification to have a hydrophilic surface by these methods, there is a problem in that restoration of hydrophobicity of the polymer film occurs in an excessively short period of time.

### BRIEF SUMMARY

One aspect of the present invention is to provide a method of modifying a surface of a hydrophobic polymer film, by which a double layer having different properties is formed on a hydrophobic polymer film through atmospheric pressure plasma polymerization, thereby improving economic feasibility and productivity.

Another aspect of the present invention is to provide a surface modified hydrophobic film, which includes a double layer including a physical barrier layer and a hydrophilic coating layer on a polymer film, thereby providing improved surface wettability and maintaining hydrophilicity of the film for a long time.

In accordance with one aspect of the present invention, a method for modifying a surface of a hydrophobic polymer film includes: placing a hydrophobic polymer film in a reactor for atmospheric pressure plasma polymerization; supplying a first reaction gas into the reactor to form a physical barrier layer on the hydrophobic polymer film via plasma deposition; and supplying a second reaction gas into the reactor to form a hydrophilic coating layer on the physical barrier layer via plasma deposition.

In accordance with another aspect of the present invention, a surface modified hydrophobic film includes: a hydrophobic polymer film, a physical barrier layer formed on the polymer film; and a hydrophilic coating layer formed on the physical barrier layer.

The method for modifying the surface of the hydrophobic polymer film according to the present invention employs an atmospheric pressure plasma deposition process, thereby enabling operation and maintenance of apparatuses and equipment at low cost, and providing efficiency in treatment of large films.

Further, in the surface-modified hydrophobic polymer film according to the present invention, the physical barrier layer is interposed between the hydrophobic polymer film and the hydrophilic coating layer, whereby the hydrophobic polymer is prevented from diffusing into the hydrophilic coating layer, thereby providing excellent surface wettability and allowing hydrophilicity of the film surface to be maintained for a long time.

### BRIEF DESCRIPTION OF THE DRAWINGS

The above and other aspects, features, and advantages of the present invention will become apparent from the detailed description of the following embodiments in conjunction with the accompanying drawings, in which:

FIG. 1 is a schematic sectional view of an atmospheric pressure plasma reactor used for manufacturing a surface-modified hydrophobic polymer film in accordance with one exemplary embodiment of the present invention;

FIG. 2 is a sectional view of a surface-modified hydrophobic polymer film in accordance with one exemplary embodiment of the present invention;

FIG. 3 is a graph depicting variation of static contact angle upon aging one example of a surface-modified hydrophobic polymer film in accordance with the present invention;

FIG. 4a and FIG. 4b are SEM images showing variation of surface characteristics of comparative examples of surface-modified hydrophobic polymer films without physical barrier layer over time; and

FIG. 5a and FIG. 5b are SEM images showing variation of surface characteristics of one example of a surface-modified hydrophobic polymer film over time, in accordance with the present invention.

### DETAILED DESCRIPTION

Exemplary embodiments of the present invention will be described with reference to the accompanying drawings. It should be understood that the present invention is not limited to the following embodiments and may be embodied in different ways. Rather, the following embodiments are given to provide complete disclosure of the invention and to provide thorough understanding of the invention to those skilled in the art. In the drawings, the thicknesses of layers and regions are exaggerated for clarity. Like components will be denoted by like reference numerals throughout the specification.

Modifications and changes can be made in various ways, and specific embodiments will be illustrated in the drawings and described in detail. However, it should be understood that the present invention is not limited to these embodiments and include all modifications, alterations and equivalents without departing from the scope and spirit of the present invention.

Unless otherwise defined herein, all terms including technical or scientific terms used herein have the same meanings as commonly understood by those skilled in the art to which the present invention belongs. It will be further understood that terms, such as those defined in commonly used dictionaries, should be interpreted as having a meaning that is consistent with their meaning in the context of the specification and relevant art and should not be interpreted in an idealized or overly formal sense unless expressly so defined herein.

In accordance with one aspect, the present invention provides a method for modifying a surface of a hydrophobic polymer film, which includes: placing a hydrophobic polymer film in a reactor for atmospheric pressure plasma polymerization; supplying a first reaction gas into the reactor to form a physical barrier layer on the hydrophobic polymer film via plasma deposition; and supplying a second reaction gas into the reactor to form a hydrophilic coating layer on the physical barrier layer via plasma deposition.

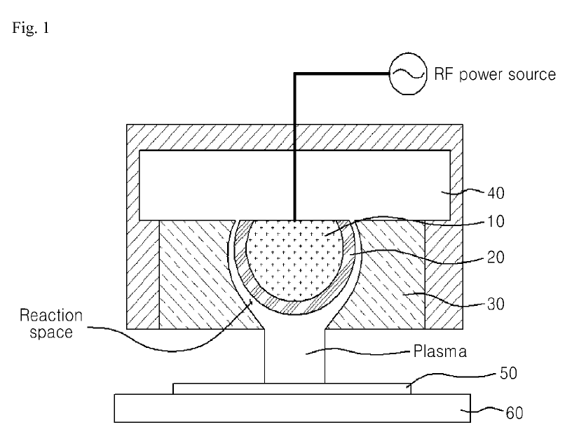

FIG. 1 is a schematic sectional view of an atmospheric pressure plasma reactor used for manufacturing a surface-modified hydrophobic polymer film in accordance with one exemplary embodiment of the present invention.

Referring to FIG. 1, an atmospheric pressure plasma reactor includes an RF power source, a source electrode 10 connected to the RF power source, a ground electrode 30 separated from the source electrode 10, a reaction space defined between the source electrode 10 and the ground electrode 30, a dielectric layer 20 formed along an outer wall of the source electrode 10, and a reaction gas supply path 40 through which a reaction gas is supplied to the reaction space. The atmospheric pressure plasma reactor further include a transfer unit 60 which can transfer a hydrophobic polymer film 50 to one side while allowing the polymer film to be exposed to plasma discharged from the atmospheric pressure plasma reactor.

The RF power source is connected to the source electrode 10 and serves to supply energy for generating plasma by ionizing a reaction gas introduced into the reactor through the reaction gas supply path. The source electrode 10 connected to the RF power source may have a cylindrical shape and is surrounded by the dielectric layer 20 comprised of an insulation material such as alumina, quartz, silicone, or the like. The dielectric layer 20 secures insulation to induce a stable electric reaction between the source electrode 10 and the ground electrode 30.

When power is supplied through the source electrode 10, an electric field is generated in the reaction space by electric reaction between the source electrode 10 and the ground electrode 30. Then, a reaction gas is introduced into the reaction space through the reaction gas supply path 40 and is changed into plasma by an electric reaction between the source electrode 10 and the ground electrode 30, so that plasma is discharged to the surface of a hydrophobic polymer film 50 on the transfer unit 60 through a nozzle head (not shown).

Since an atmospheric pressure plasma polymerization system including such an atmospheric pressure plasma reactor does not need vacuum equipment, installation, operation and maintenance of the system can be realized at low cost and plasma treatment can be performed regardless of chamber size. Thus, such an atmospheric pressure plasma polymerization system is advantageous in plasma treatment of large films.

A hydrophobic polymer film is placed within the reactor for atmospheric pressure plasma polymerization. The hydrophobic polymer film may be disposed on the transfer unit to be moved towards one side. The hydrophobic polymer film may be comprised of at least one selected from polydimethylsiloxane (PDMS), polystyrene (PS), polymethylmethacrylate (PMMA), polyvinylidene fluoride (PVDF), polysulfone (PSF), polyethersulfone (PES), polyetherimide (PEI), polyethyleneterephthalate (PET), polyimide (PI), polyethylene (PE), polypropylene (PP), and polycarbonate (PC). However, it should be noted that the hydrophobic polymer film is not limited thereto and may include any film comprised of a hydrophobic polymer.

Then, a first reaction gas is supplied into the reactor to form a physical barrier layer on the hydrophobic polymer film by plasma deposition. In this case, when the first reaction gas is supplied into the reactor after supplying an inert gas such as helium, argon, and the like as a carrier gas into the reactor through the gas supply path, the amount of active radicals can be maximized. The first reaction gas may include carbon and hydrogen.

For example, saturated hydrocarbon or unsaturated hydrocarbon, such as CₙH₂ₙ₊₂, CₙH₂ₙ, CₙH₂ₙ₋₂, CₙH₂ₙ₊₁, or the like, or hydrocarbon compounds obtained by coupling the saturated hydrocarbon or unsaturated hydrocarbon with O, N, Cl, Br, and the like may be supplied as the first reaction gas. The carrier gas may be supplied at a flux of 1 slm to 20 slm and the first reaction gas may be supplied at a flux of 10 sccm to 200 sccm.

In addition, an output power of the RF power source for plasma deposition may be in the range of 20 W to 300 W. When power is supplied to the reactor through the source electrode, an electric field is generated in the reaction space via electric reaction between the source electrode and the ground electrode. The carrier gas and the first reaction gas supplied through the gas supply path are changed into plasma in the reaction space by the electric reaction between the source electrode and the ground electrode, and the plasma is provided to the surface of the hydrophobic polymer film disposed on the transfer unit through the nozzle head. At this time, the distance between the nozzle head of the plasma source and the hydrophobic polymer film may be adjusted within the range of 0.1 mm to 5 mm. Further, the plasma deposition process may be repeatedly carried out 10 to 300 times at a processing speed of 1˜100 mm/s using the transfer unit on which the hydrophobic polymer film is disposed. Through the plasma deposition process, a physical barrier layer is formed on the hydrophobic polymer film to prevent hydrophobic polymer molecules from diffusing into the hydrophilic coating layer.

Then, a second reaction gas is supplied into the reactor to form a hydrophilic coating layer on the physical barrier layer via plasma deposition. In this case, when the second reaction gas is supplied into the reactor after supplying an inert gas such as helium, argon, and the like as a carrier gas into the reactor through a gas supply path, the amounts of active radicals can be maximized. The second reaction gas may be prepared by evaporating a liquid reaction material and mixing the reaction gas with oxygen O₂. At this time, the reaction material to be used may be at least one selected from the group consisting of tetraethylorthosilicate (TEOS), tetramethyldisiloxane (TMDSO), divinyltetramethyldisiloxane (DVTMDSO), methyltrimethoxysilane (MTMOS), and octamethylcyclotetrasiloxane (OMCATS). These reaction materials may be applied in a vaporized state through a carrier gas. The carrier gas may be an inert gas such as helium, argon, and the like. The carrier gas for evaporating the reaction material and the carrier gas for maximizing the amount of active radicals may be separately supplied. The carrier gas may be supplied at a flux of 1 slm to 20 slm and the second reaction gas may be supplied at a flux of 20 sccm to 300 sccm.

In addition, an output power of the RF power source for plasma deposition may be in the range of 20 W to 300 W. When power is supplied to the reactor through the source electrode, an electric field is generated in the reaction space via electric reaction between the source electrode and the ground electrode. The carrier gas and the second reaction gas supplied through the gas supply path are changed into plasma in the reaction space by the electric reaction between the source electrode and the ground electrode, and the plasma is provided to the surface of the hydrophobic polymer film disposed on the transfer unit through the nozzle head. At this time, the distance between the nozzle head of the plasma source and the hydrophobic polymer film may be adjusted within the range of 0.1 mm to 5 mm. Further, the plasma deposition process may be repeatedly carried out 10 to 300 times at a processing speed of 1˜100 mm/s using the transfer unit on which the hydrophobic polymer film is disposed. Through the plasma deposition process, a hydrophilic coating layer is formed on the physical barrier layer to modify the surface of the hydrophobic polymer film into a hydrophilic surface.

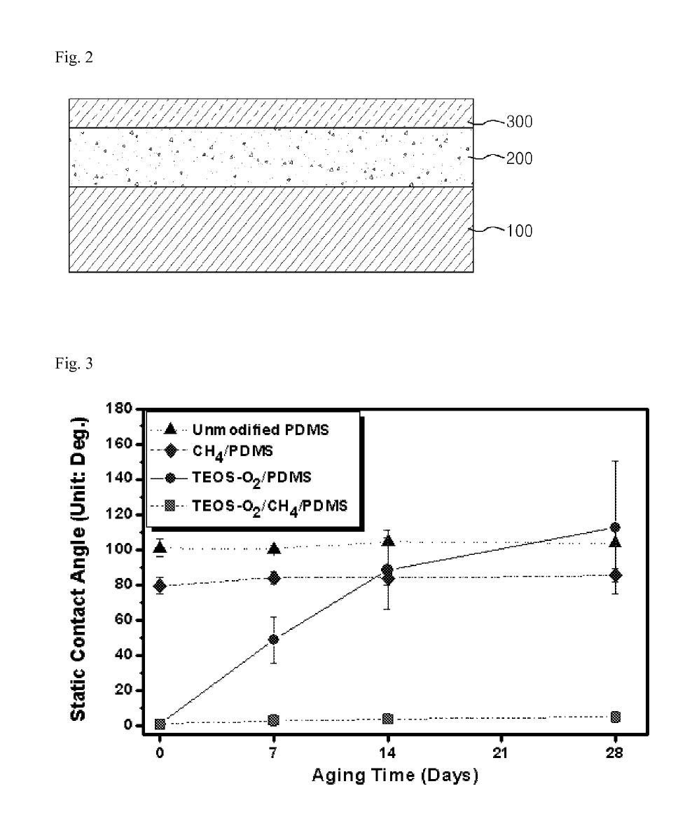

FIG. 2 is a sectional view of a surface-modified hydrophobic polymer film in accordance with one exemplary embodiment of the present invention

Referring to FIG. 2, a surface-modified hydrophobic polymer film according to one exemplary embodiment of the invention includes a hydrophobic polymer film, a physical barrier layer formed on the hydrophobic polymer film, and a hydrophilic coating layer formed on the physical barrier layer.

The hydrophobic polymer film 100 may be comprised of at least one selected from polydimethylsiloxane (PDMS), polystyrene (PS), polymethylmethacrylate (PMMA), polyvinylidene fluoride (PVDF), polysulfone (PSF), polyethersulfone (PES), polyetherimide (PEI), polyethyleneterephthalate (PET), polyimide (PI), polyethylene (PE), polypropylene (PP), and polycarbonate (PC). However, it should be noted that the hydrophobic polymer film is not limited thereto and may include any film comprised of a hydrophobic polymer.

The physical barrier layer 200 is formed on the hydrophobic polymer film 100 and serves as a barrier with respect to the hydrophilic coating layer described below to prevent diffusion of hydrophobic polymer molecules. The physical barrier layer may include carbon and hydrogen. For example, the physical barrier layer may be comprised of saturated hydrocarbon or unsaturated hydrocarbon, such as CₙH₂ₙ₊₂, CₙH₂ₙ, CₙH₂ₙ₋₂, CₙH₂ₙ₊₁, or the like, or hydrocarbon compounds obtained by coupling the saturated hydrocarbon or unsaturated hydrocarbon with O, N, Cl, Br, and the like.

The hydrophilic coating layer 300 is formed on the physical barrier layer 200, and may maintain super-hydrophilic properties due to the physical barrier layer 200, which is interposed between the hydrophobic polymer film 100 and the hydrophilic coating layer 300 to prevent the hydrophobic polymer molecules from diffusing from the polymer film into the hydrophilic coating layer 300. The hydrophilic coating layer 300 may be comprised of at least one selected from, for example, silicon oxide (SiO₂), polyvinyl alcohol, polyacrylic acid, polyvinylpyrrolidone, polyvinylamine, and hydroxylethyl methacrylic acid (HEMA). However, it should be understood that the hydrophilic coating layer is not limited thereto and may be comprised of any hydrophilic material.

Next, the present invention will be described with reference to examples. It should be noted that the following examples are provided for illustration only and do not limit the scope of the present invention.

### EXAMPLE

### 1. Preparation of PDMS Film

A PDMS prepolymer (Sylgard 184) and a crosslinking agent were mixed in a weight ratio of 10:1 and stirred. Then, the mixture was placed on a 4″ polystyrene Petri dish and inserted into a vacuum desiccator to remove bubbles generated during mixing and stirring. Then, the mixture was cured in an oven at 80° C. for 90 minutes to provide a 1 mm thick PDMS film, which in turn was cut to a size of 2×4 cm².

### 2. Deposition of Physical Barrier Layer

Then, plasma was generated in an atmospheric pressure plasma polymerization system with an RF power of 13.56 MHz. An output RF power for plasma deposition was 200 W. Super-purity He was used as a carrier gas and a mixture of CH₄ (5%) and Ar (95%) was used as a reaction gas to form a physical barrier layer on the PDMS film. At this time, the carrier gas was supplied at a flux of 15 slm and the reaction gas was supplied at 1 slm. The distance between the nozzle head of the plasma source and the PDMS film was adjusted to 1.5 mm. Plasma deposition was carried out 90 times at 20 mm/s.

### 3. Deposition of Hydrophilic Coating Layer

Then, a mixture of TEOS and O₂ was supplied as a reaction gas to form a hydrophilic SiOₓ layer on the physical barrier layer. An output RF power for plasma deposition was 200 W. High-purity He was supplied as a carrier gas at a flux of 5 slm. The reaction gas was a mixture of TEOS evaporated by Ar supplied at 1 slm and O₂ supplied at 150 sccm. The distance between the nozzle head of the plasma source and the PDMS film was adjusted to 2 mm, and plasma deposition was carried out 90 times at 20 mm/s.

FIG. 3 is a graph depicting variation of a static contact angle upon aging one example of a surface-modified hydrophobic polymer film in accordance with the invention.

Referring to FIG. 3, the term “static contact angle” means an angle between a surface of a water droplet having a predetermined size and a surface of an object when the water droplet is placed on the surface of the object in a horizontal state. A lower contact angle indicates greater hydrophilicity and better surface wettability.

When surface modification was not carried out, PDMS and CH₄/PDMS had static contact angles of about 100 degrees and about 85 degrees, respectively. Thus, it could be seen that they have hydrophobic surfaces. On the other hand, for TEOS-O₂/PDMS, that is, when a hydrophilic coating layer was formed on a hydrophobic polymer film without a physical barrier layer therebetween, the film initially exhibited hydrophilicity at a static contact angle of 0, and gradually increased in static contact angle to about 113 degrees over 28 days. Thus, it could be seen that the the hydrophobic surface of PDMS was restored. On the contrary, for TEOS-O₂/CH₄/PDMS, that is, when a physical barrier layer and a hydrophilic coating layer were sequentially formed on the polymer film, the static contact angle was maintained at about 5 degrees or less for 28 days. Thus, it could be seen that the surface of the PDMS film was modified into a super hydrophilic surface and the super-hydrophilicity of the film were maintained for 28 days.

TABLE 1

| | | | | | | Chemical bonding (area %) | | | |
|---|---|---|---|---|---|---|---|---|---|
| | Composition (at. %) | | | | | C 1s peaks | | Si 2p peaks | |
| Sample Kind | C | O | Si | O/Si | O/C | —C—C— | —C—O— | Silicone | Silicate |
| Unmodified | 44.9 | 27.2 | 27.9 | 0.97 | 0.60 | 95.5% | 4.5% | 71.8% | 28.2% |
| PDMS | | | | | | | | | |
| CH₄/PDMS | 57.3 | 22.6 | 20.1 | 1.12 | 0.39 | 92.3% | 7.7% | 70.7% | 29.3% |
| TEOS- | 23.4 | 44.8 | 31.8 | 1.41 | 1.91 | 84.9% | 15.1% | 17.8% | 82.2% |
| O₂/PDMS | | | | | | | | | |
| TEOS- | 20.7 | 47.1 | 32.2 | 1.46 | 2.27 | 91.9% | 8.1% | 18.4% | 81.6% |
| O₂/CH₄/PDMS | | | | | | | | | |

Table 1 shows XPS analysis data according to sample type.

Referring to Table 1, it can be seen that PDMS films not subjected to surface modification essentially consist of —C—C— bonds. However, for the PDMS film subjected to surface modification, the amount of —C—C— bonds decreases whereas the amount of —C—O— bonds increases. For TEOS-O₂/CH₄/PDMS and TEOS-O₂/PDMS films, the ratio of O/Si is increased more and less, and the ratio of O/C is rapidly increased. From this analysis result, it can be seen that coating layers having different compositions are deposited on the hydrophobic polymer film according to conditions of the reaction gas and surface modification during atmospheric pressure plasma polymerization deposition. Improvement of the C 1 s peak and the Si 2 p peak indicates that these two elements are present in two different chemical states. From this result, it can be seen that hydrophilicity of the PDMS film surface subjected to surface modification results from coupling between functional groups containing oxygen on the surface thereof.

Further, it can be seen that the ratio of silicone/silicate in the PDMS film including TEOS-O₂, that is, the hydrophilic coating layer, is opposite to the ratio of silicone/silicate in the PDMS film not subjected to hydrophilic treatment, that is, not containing TEOS-O₂.

At this time, it can be seen that, in the PDMS film including TEOS-O₂, the amount of silicate is about 4 times the amount of silicone. Due to a negative (−) polarity of the chemical bond, a silicate functional group exhibits more hydrophilicity than a silicone functional group, so that a surface containing a higher amount of silicate exhibits more hydrophilicity. As a result, it can be seen that the ratio of silicone/silicate is a main factor determining hydrophilicity of the polymer film subjected to surface modification through atmospheric pressure plasma polymerization with TEOS-O₂.

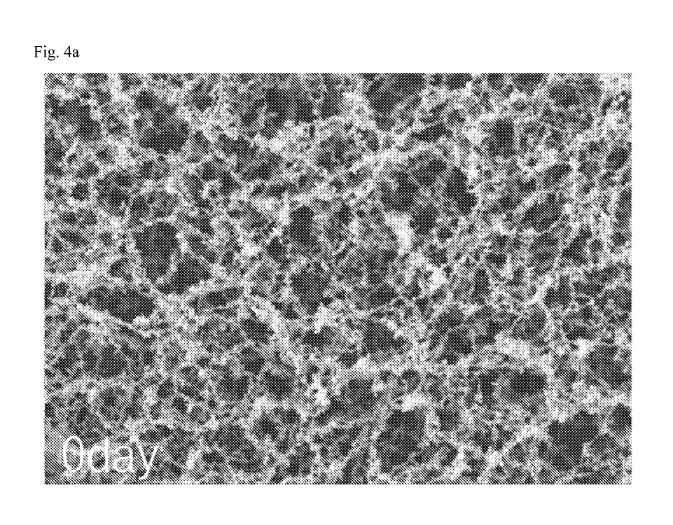

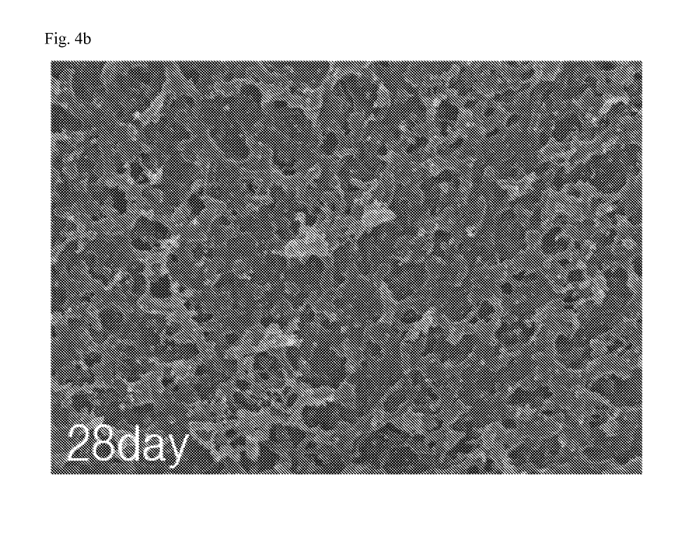

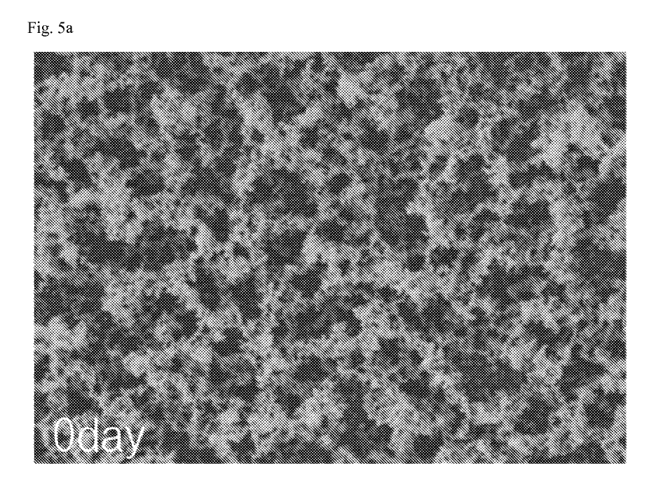

FIG. 4a and FIG. 4b are SEM images showing variation of surface characteristics of comparative examples of surface-modified hydrophobic polymer films over time.

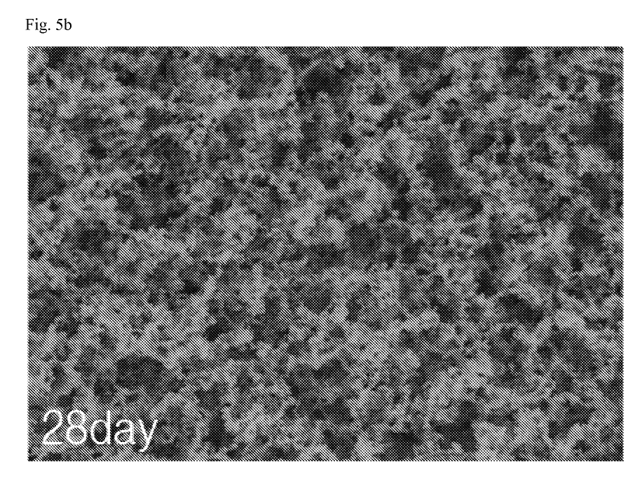

FIG. 5a and FIG. 5b are SEM images showing variation of surface characteristics of one example of a surface-modified hydrophobic polymer film over time, in accordance with the present invention.

Referring to FIGS. 4a and 4b, the surface of the PDMS film is formed with a SiOₓ coating layer using TEOS-O₂ without forming a CH₄ layer. Comparing an SEM image of the surface of the PDMS film in 0 day with an SEM image thereof after 28 days, it could be seen that the surface morphology of the SiOₓ layer was significantly changed. It was determined that PDMS molecules were consistently diffused into the SiOₓ layer, thereby reducing hydrophilicity of the film.

Referring to FIGS. 5a and 5b, for TEOS-O₂/CH₄/PDMS in which a CH₄ layer and a SiOₓ layer were sequentially formed on the PDMS film, it could be seen that there was no difference between the SEM image of the PDMS film surface in 0 day and the SEM image thereof after 28 days. In other words, in the surface-modified hydrophobic polymer film according to one example of the present invention, the hydrocarbon layer interposed between the hydrophilic coating layer and the polymer film acts as a barrier to prevent diffusion of the PDMS molecules, thereby maintaining super hydrophilicity for a long time.

Although some exemplary embodiments have been described herein, it should be understood by those skilled in the art that these embodiments are given by way of illustration only, and that various modifications, variations, and alterations can be made without departing from the spirit and scope of the present invention. Further, the scope of the present invention should be interpreted according to the following appended claims as covering all modifications or variations induced from the appended claims and equivalents thereof.

What is claimed is:

1. A method for modifying a surface of a hydrophobic polymer film, comprising:
placing a hydrophobic polymer film in a reactor for atmospheric pressure plasma polymerization;
supplying a first reaction gas into the reactor to form a physical barrier layer on the hydrophobic polymer film via plasma deposition; and
supplying a second reaction gas into the reactor to form a hydrophilic coating layer on the physical barrier layer via plasma deposition.

2. The method according to claim 1, wherein the hydrophobic polymer film comprises at least one selected from polydimethylsiloxane (PDMS), polystyrene (PS), polymethylmethacrylate (PMMA), polyvinylidene fluoride (PVDF), polysulfone (PSF), polyethersulfone (PES), polyetherimide (PEI), polyethyleneterephthalate (PET), polyimide (PI), polyethylene (PE), polypropylene (PP), and polycarbonate (PC).

3. The method according to claim 1, wherein the first reaction gas comprises at least one selected from CH₄, C₂H₄, C₂H₆, C₃H₈, and C₂H₂.

4. The method according to claim 1, wherein the second reaction gas is a mixture obtained by evaporating a liquid reaction material and mixing the reaction material with oxygen.

5. The method according to claim 4, wherein the reaction material comprises at least one selected from tetraethylorthosilicate (TEOS), tetramethyldisiloxane (TMDSO), divinyltetramethyldisiloxane (DVTMDSO), methyltrimethoxysilane (MTMOS), and octamethylcyclotetrasiloxane (OMCATS).

6. The method according to claim 1, wherein the first reaction gas or the second reaction gas is supplied together with a carrier gas.

7. The method according to claim 6, wherein the carrier gas is supplied at a flux of 1 slm to 20 slm.

8. The method according to claim 1, wherein the first reaction gas is supplied at a flux of 10 sccm to 200 sccm.

9. The method according to claim 1, wherein the second reaction gas is supplied at a flux of 20 sccm to 300 sccm.

10. A surface-modified hydrophobic polymer film comprising:
a hydrophobic polymer film;
a physical barrier layer formed on the polymer film; and
a hydrophilic coating layer formed on the physical barrier layer.

11. The surface-modified hydrophobic polymer film according to claim 10, wherein the hydrophobic polymer film comprises at least one selected from polydimethylsiloxane (PDMS), polystyrene (PS), polymethylmethacrylate (PMMA), polyvinylidene fluoride (PVDF), polysulfone (PSF), polyethersulfone (PES), polyetherimide (PEI), polyethyleneterephthalate (PET), polyimide (PI), polyethylene (PE), polypropylene (PP), and polycarbonate (PC).

12. The surface-modified hydrophobic polymer film according to claim 10, wherein the physical barrier layer comprises hydrocarbon or a hydrocarbon compound.

13. The surface-modified hydrophobic polymer film according to claim 10, wherein the hydrophilic coating layer comprises at least one selected from silicon oxide, polyvinyl alcohol, polyacrylic acid, polyvinylpyrrolidone, polyvinylamine, and hydroxylethyl methacrylic acid.
